(19) United States
(12) Patent Application Publication
(10) Pub. No.: US 2005/0098797 A1
(43) Pub. Date: May 12, 2005

(54) Photoelectric conversion device and image sensor IC

(76) Inventor: Satoshi Machida, Chiba-shi (JP)

Correspondence Address: ADAMS & WILKS, 31ST FLOOR, 50 BROADWAY, NEW YORK, NY, 10004, US

(21) Appl. No.: 10/984,309

(22) Filed: Nov. 9, 2004

(30) Foreign Application Priority Data
Nov. 10, 2003 (JP) 2003-379595

(51) Int. Cl. H01L 31/072

(52) U.S. Cl. 257/187; 257/83

(57) ABSTRACT

To provide a photoelectric conversion device having a high S/N ratio at a low cost. The photoelectric conversion device includes a light-receiving element that includes: a first semiconductor region of a first conductivity type; a second semiconductor region of a second conductivity type formed in the first semiconductor region; and a gate electrode formed close to the second semiconductor region through an insulator. In the photoelectric conversion device, a surface state of the first semiconductor region below the gate electrode can be controlled between two states consisting of an inversion state and an: accumulation state.

### BACKGROUND OF THE INVENTION

1. Field of the Invention

The present invention relates to a photoelectric conversion device for converting an optical signal to an electric signal. The invention also relates to an image sensor IC applied to an image reading apparatus such as a facsimile machine or an image scanner, and a close contact type image sensor having plural image sensor ICs mounted thereon. The invention also relates to a photoelectric conversion device applied to an image pick-up device such as a digital camera. In particular the invention relates to an improvement in sensitivity of a light-receiving element and reduction in random noise resulting from a reset operation.

2. Description of the Related Art

Up to now, a photoelectric conversion device (light-receiving element) has undergone many improvements aiming to enhance a sensitivity of the photoelectric conversion device and reduce a random noise for improving an S/N ratio.

As regards the sensitivity of the light-receiving element, photogenerated carriers Qp are accumulated in a capacitance Cpd in a photodiode portion with a PN junction diode, and upon converting the carriers into a voltage, an optical signal voltage Vp converted from the photogenerated carriers is represented by the following equation:
Vp=Qp/Cpd (1)
Thus, in order to improve the sensitivity of the light-receiving element, it is necessary to trap the photogenerated carriers Qp generated in a light-receiving area at a PN junction, in sufficient amounts and to reduce the capacitance Cpd in the photodiode portion. To that end, as shown in FIG. 17, P-type regions 1, 1′ as small diffusion regions are formed in plural inside respective light-receiving regions (N-type semiconductor substrate) of plural openings 4 surrounded by a light-shielding film 3. An attempt has been made to trap the photogenerated carriers Qp generated in the light-receiving region as many as possible in the P-type regions 1, 1′ as the diffusion regions and in addition, to reduce the capacitance Cpd in the photodiode portion (see JP 11-112006 A (p. 9, FIG. 1), for example).

Further, in a system for initializing a photodiode, a reset noise Vn is generated chiefly because a random noise of an element responsible for initialization is generated at the time of initialization. The reset noise Vn is represented by the following equation:
Vn=\sqrt{(kT/Cpd)} (2)
(where k: Boltzmann constant, T: temperature (K°))
Then, an S/N ratio is derived from the equations (1) and (2) as follows:
Vp/Vn=Qp·{square root over ((1/(kTCpd)))} (3)
Hence, in order to improve the S/N ratio, it is necessary to increase the photogenerated carrier Qp and reduce the capacitance Cpd of the photodiode portion.

There is a method of preventing generation of reset noises by simultaneously performing a reset operation and a charge transfer operation with a, buried diode. However, this method encounters a problem in that a special manufacturing process is necessary for obtaining the buried diode because it cannot be prepared through a standard CMOS process.

In addition, the buried diode requires a large junction capacitance, leading to the large capacitance Cpd of the photodiode portion and reduction in sensitivity.

The sensitivity can be increased through amplification in a subsequent signal processing circuit. In this case, however, a thermal noise in each circuit is similarly amplified, making it difficult to attain the high S/N ratio.

In light of the above, an attempt has been made to cancel reset noises by providing nose signal holding means as shown in FIG. 18, with a view to canceling the reset noises on a circuit scale (see JP 09-205588 A (p. 7, FIG. 1), for example). In the case of using a phototransistor as the light-receiving element, the phototransistor has an amplifying function and thus enables high sensitivity. However, this involves a disadvantage in that charges remain between a base and an emitter, so an afterimage appears. The photodiode is free of such a disadvantage.

However, this kind of photoelectric conversion device causes the following problems.

With the photoelectric conversion device of FIG. 17, because of its small diffusion region, a rate for trapping photocharges, which are generated around the outer periphery of the light-receiving region, in the diffusion region drops. Therefore, the photogenerated carrier Qp is reduced.

With the photoelectric conversion device of FIG. 18, noise signal holding means should be provided in a number corresponding to the number of light-receiving elements, leading to a large chip area. In addition, the sensitivity of the light-receiving element is equivalent to the conventional ones. In order to obtain a high sensitivity, an amplification rate in the subsequent signal processing circuit needs to increase to improve the sensitivity. In this case, thermal noises in other circuits than the reset circuit are similarly amplified, making it difficult to attain a high S/N ratio.

### SUMMARY OF THE INVENTION

In order to solve the above-mentioned problems of conventional cases, the present invention provides a photoelectric conversion device, including a light-receiving element that includes: a first semiconductor region of a first conductivity type; a second semiconductor region of a second conductivity type formed in the first semiconductor region; and a gate electrode formed close to the second semiconductor region through an insulator, in which a surface state of the first semiconductor region below the gate electrode can be controlled between two states consisting of an inversion state and an accumulation state.

Also, the photoelectric conversion device further includes: reset means for initializing the second semiconductor region; and amplifying means for generating an amplification signal based on a signal of the second semiconductor region.

Also, in the photoelectric conversion device, the surface of the first semiconductor region below the gate electrode is brought into the inversion state when the light-receiving element accumulates photo charges, and the surface of the first semiconductor region below the gate electrode is brought into the accumulation state when the light-receiving element reads an optical signal.

Also, in the photoelectric conversion device, the surface of the first semiconductor region below the gate electrode is brought into the inversion state when the light-receiving element is initialized. Alternatively, in the photoelectric conversion device, the surface of the first semiconductor region below the gate electrode is brought into the accumulation state when the light-receiving element is initialized.

Also, in the photoelectric conversion device, the gate electrode is formed of polysilicon or a transmissive conductive film. Further, the present invention provides an image sensor which has the photoelectric conversion device.

According to the photoelectric conversion device, at the time of accumulating the photocharges, a substrate below the gate electrode is brought into an inversion state, and thus a channel and depletion layer are formed in the substrate, and photocharges generated in a light-receiving region can be trapped in plenty, together with the second semiconductor region. Consequently, a photogenerated carrier Qp can be increased.

The gate electrode is formed of polysilicon, and thus a part of light passes through the gate electrode, whereby reduction in photogenerated carrier Qp can be minimized.

Also, upon reading an optical signal, the substrate below the gate electrode is brought into the accumulation state, so the photocharges accumulated in the channel below the gate electrode move to the second semiconductor region, preventing the loss of the photogenerated carriers Qp. At this time, a capacitance Cpd of a photodiode portion includes no capacitance below the gate electrode and can be reduced, whereby an optical signal voltage Vp is increased as derived from the,equation (1).

Also, upon initializing the light-receiving element, the substrate below the gate electrode is brought into the inversion state so that the capacitance Cpd of the photodiode portion includes a gate capacitance, whereby a reset noise Vn can be reduced as derived from the equation (2).

Further, because of the large optical signal voltage Vp, it is unnecessary to increase an amplification rate of the signal processing circuit. Hence, an influence of the voltage Vn and the thermal noises of other circuits than an initializing circuit is reduced to thereby attain a high S/N ratio.

The above structure can be attained without requiring any additional steps in a standard CMOS process.

In addition, the gate electrode is formed using a conductive film transmissive of light with an objective wavelength (detection target), thereby avoiding the reduction in transmissivity in the gate electrode and offering a larger amount of photogenerated carriers Qp. Consequently, a high S/N ratio can be obtained.

Further, most of the light-receiving element is covered with the gate electrode with a constant potential, whereby a radiation noise transmitted from above the light-receiving element can be blocked.

As described above, the photoelectric conversion device having a high S/N ratio can be provided at a low cost.

### BRIEF DESCRIPTION OF THE DRAWINGS

In the accompanying drawings:

FIG. 1 is a plan view showing a light-receiving element of a photoelectric conversion device according to the embodiment of the present invention;

FIG. 2 is a sectional view taken along a line A-A′ of FIG. 1;

FIG. 3 is a schematic diagram showing an image sensor IC according to the embodiment of the present invention;

FIG. 4 is a schematic diagram showing a close contact type image sensor according to the embodiment of the present invention;

FIG. 5 is a schematic circuit diagram of the photoelectric conversion device according to the embodiment of the present invention;

FIG. 6 is an overall structural view of the photoelectric conversion device according to the embodiment of the present invention;

FIG. 7 is a block diagram showing a signal processing circuit according to the embodiment of the present invention;

FIG. 8 is a circuit diagram showing a sample/hold circuit according to the embodiment of the present invention;

FIG. 9 is a circuit diagram showing a buffer circuit according to the embodiment of the present invention;

FIG. 10 is a circuit diagram showing an amplifier circuit according to the embodiment of the present invention;

FIG. 11 is a circuit diagram showing a subtracter according to the embodiment of the present invention;

FIG. 12 is a circuit diagram showing a clamp circuit according to the embodiment of the present invention;

FIG. 13 is a timing chart illustrative of a first operation method for the signal processing circuit and photoelectric conversion device according to the embodiment of the present invention;

FIG. 14 is a timing chart illustrative of a second operation method for the signal processing circuit and photoelectric conversion device according to the embodiment of the present invention;

FIG. 15 is a timing chart illustrative of a third operation method for the signal processing circuit and photoelectric conversion device according to the embodiment of the present invention;

FIG. 16 is a timing chart illustrative of a fourth operation method for the signal processing circuit and photoelectric conversion device according to the embodiment of the present invention;

FIG. 17 is a plan view showing a light-receiving element of a conventional photoelectric conversion device; and

FIG. 18 is a circuit diagram and a timing chart of the conventional photoelectric conversion device.

### DETAILED DESCRIPTION OF THE PREFERRED EMBODIMENTS

Hereinafter, the present invention will be described with reference to the accompanying drawings.

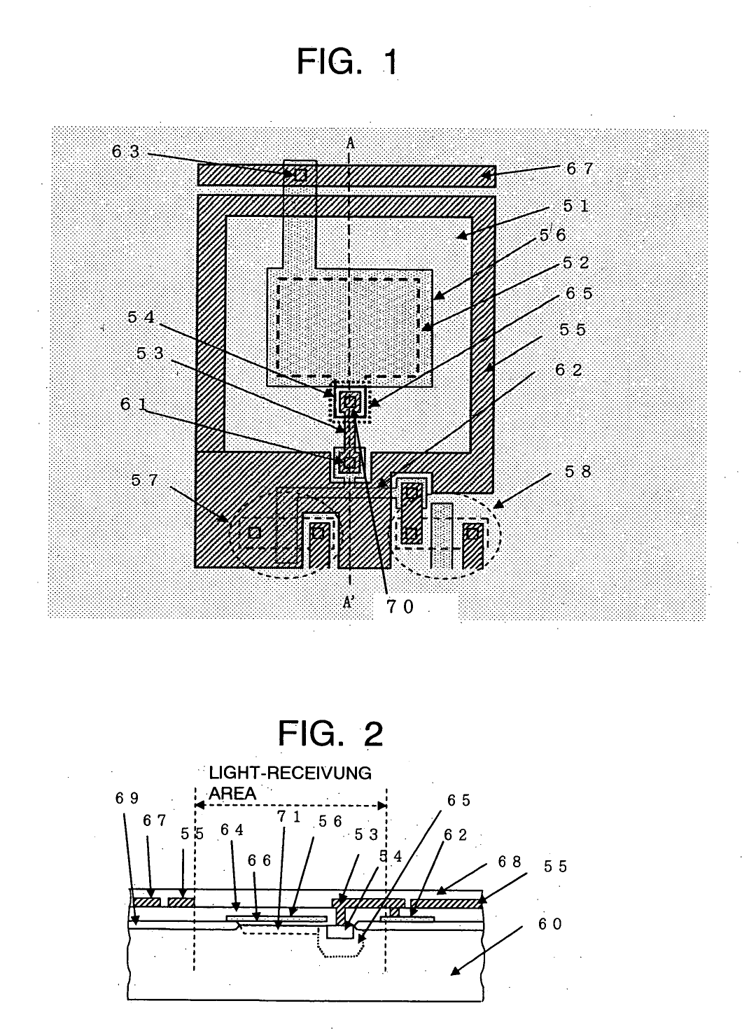

FIG. 1 is a plan view showing a light-receiving element of a photoelectric conversion device according to the present invention, and FIG. 2 is a sectional view taken along the line A-A′ of FIG. 1.

The light-receiving element of the present invention includes: a P-type semiconductor substrate region 60 as a first semiconductor region of a first conductivity type formed within a pixel region 51; an N-type semiconductor region 54 as a second semiconductor region of a second conductivity type; and a gate electrode 56 formed in proximity to the N-type semiconductor region 54 through a gate insulating film 66. The gate electrode 56 is formed of polysilicon or a conductive film transmissive of light having an objective wavelength (detection target).

The gate electrode 56 is electrically connected to a control signal line 67 formed of, for example, Al (aluminum) through a contact 63. The N-type semiconductor region 54 as a photodiode diffusion region is formed concurrently with the formation of N+ regions of source/drain regions in an NMOS transistor. In addition, a capacitance Cpd of a photodiode portion can be further reduced by forming a thin N-type diffusion layer 65 as an N-type diffusion region around the N-type semiconductor region 54 (N+).

An output signal from the photodiode is inputted to a reset circuit 58 for initializing the photodiode and a source follower circuit 57 for generating an amplification signal, via an Al wiring 53 and a polysilicon wiring 62 through the N-type semiconductor region 54. The reset circuit 58 is composed of, for example, an NMOS transistor. The source follower circuit 57 is composed of, for example, a PMOS transistor.

The Al wiring 53 is connected to the N-type semiconductor region 54 through a contact 70 and in turn to the polysilicon wiring 62 through a contact 61. An Al 55 having a VSS potential shields the surroundings of the light-receiving element from light.

Denoted by a dotted line 52 is a boundary of a LOCOS oxide film 69. Further, the Al wiring 53 and the control signal line 67 are formed on an intermediate (interlayer) insulating film 64.

At the time of accumulating photocharges, the control signal line 67 is used to set the potential of the gate electrode 56 higher than a potential of the substrate region 60. At this time, a substrate potential (conductivity) is inverted into an N-type one below the gate electrode 56 to thereby form a channel 71 and establish electrical connection with the N-type semiconductor region 54. In such a state, a depletion layer exists between the channel 71 and the P-type semiconductor region 60, where photocharges generated in response to incident light are trapped.

Next, if the control signal line 67 is used to set the potential of the gate electrode 56 lower than the potential of the substrate region 60, the channel 71 disappears. However, the photocharges accumulated in the channel 71 move to the adjacent N-type semiconductor region 54 to thereby avoid the loss of photocharges. In this case, the channel 71 disappears and hence a capacitance of the channel 71 is excluded. As a result, a capacitance Cpd of the photodiode portion is reduced down to the total capacitance of a junction capacitance of the N-type semiconductor region 54, a gate capacitance of the source follower circuit 57, a drain capacitance of the reset circuit 58, and capacitances of the wirings 53 and 62. In this state, the optical signals are read out through the source follower circuit 57.

As described above, the photocharges trapped in a wide area are moved to the small capacitance Cpd of the photodiode portion and read out, whereby a high sensitivity is allowed as derived from the equation (1). Upon the initialization operation, the control signal line 67 is used to set the potential of the gate electrode 56 higher than the potential of the substrate region 60. At this time, the substrate potential (conductivity) is inverted into an N-type one below the gate electrode 56, so the channel 71 is formed. In this state, the reset circuit 58 is adapted to initialize (reset) the potential of the N-type semiconductor region 54. At this point, the N-type semiconductor region 54 and the channel 71 are electrically kept at the same level, and thus the capacitance of the gate electrode 56 and the channel 71 counts in the capacitance Cpd of the photodiode portion, resulting in an extremely large capacitance value. Hence, as derived from the equation (2), a reset noise Vn reduces.

Also, most of the light-receiving element is covered with the gate electrode 56 with a constant potential, whereby a radiation noise transmitted from above the light-receiving element can be blocked as well.

Referring next to FIG. 2, a manufacturing method will be described. An N well (not shown) as a substrate of a PMOS transistor is formed above a P-type substrate concurrently with the formation of the N-type diffusion layer 65 of the photodiode. The N-type diffusion layer 65 maybe formed independently of the N well or otherwise omitted. Next, the LOCOS oxide film 69 is formed. Following this, a gate region of the transistor, and the polysilicon gate electrode 56 and the polysilicon wiring 62 are formed at the same time.

Subsequently, the source/drain regions of the, NMOS transistor and the N-type semiconductor region 54 of the photodiode are simultaneously formed. Then, the intermediate insulating film 64 and a contact hole are formed. After that, the Al wiring and the Al 55 are formed at the same time. A passivation film 68 is then formed.

In the above explanation, the P-type substrate may be replaced by an N-type substrate, and a P-type semiconductor may substitute for each of the N-type diffusion region 54 and the N-type diffusion layer 65.

As discussed above, according to this embodiment, it is possible to manufacture an objective one without requiring any additional steps in a standard. CMOS process (process for manufacturing a CMOS transistor with a single Al layer). The gate electrode 56 may be formed by using any conductive film transmissive of incident light with a given wavelength, instead of using polysilicon. For example, a conductive film formed of ITO etc. may be formed. Also, the potential of the gate electrode 56 is appropriately set to either a higher potential or a lower potential. In this, embodiment employing the P-type substrate, the higher potential applied to the gate electrode 56 means such a voltage as to induce an inversion layer right below the gate electrode 56, while the lower potential means such a voltage as to cause the inversion layer to disappear.

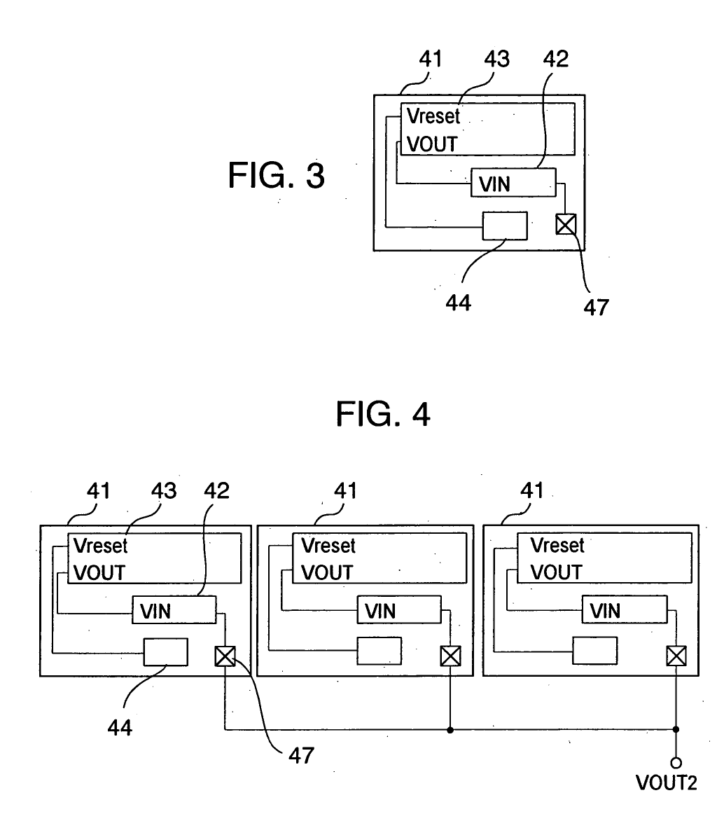

FIG. 3 is a schematic diagram showing an image sensor IC according to an embodiment of the present invention. An image sensor IC 41 includes: a signal processing circuit 42; a photoelectric conversion device 43; a reference voltage circuit 44; and a signal output terminal 47. A common signal line of the photoelectric conversion device 43 is connected to an input terminal of the signal processing circuit 42 and an output terminal of the signal processing circuit 42 is in turn connected to the signal output terminal 47.

FIG. 4 is a schematic diagram showing a close contact type image sensor composed of the image sensor ICs 41 of FIG. 3. The close contact type image sensor includes the three image sensor ICs 41. The signal output terminals 47 of all the image sensor ICs 41 are connected at an external portion, and signals are outputted to the outside through a terminal VOUT2.

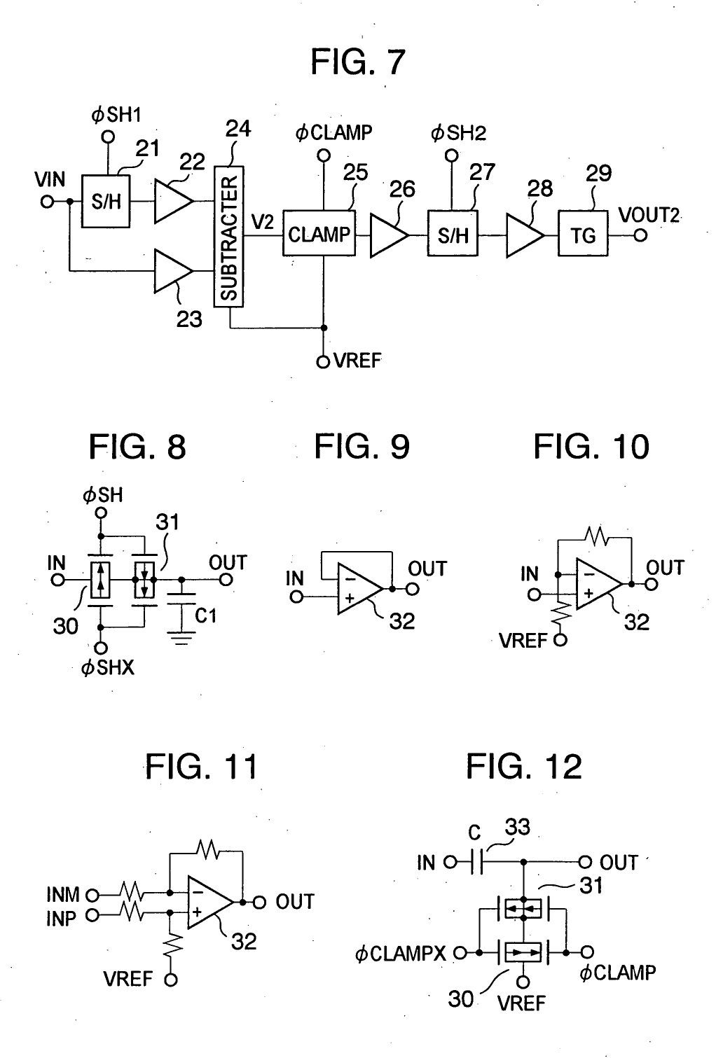

FIG. 7 is a block diagram showing the signal processing circuit 42 according to the embodiment of the present invention. A signal inputted to an input terminal YIN is inputted to a sample/hold circuit 21 or a buffer amplifier 23. An output signal from the sample/hold circuit 21 is inputted into a buffer amplifier 22. Output signals from the buffer amplifiers 22 and 23 are inputted to a subtracter 24. An output signal from the subtracter 24 is inputted to a clamp circuit 25. The subtracter 24 and the clamp circuit 25 can have the same reference voltage and are connected to a VREF terminal. An output signal from the clamp circuit 25 is inputted to a buffer amplifier 26. Here, an amplifier circuit may be provided in place of the buffer amplifier 26. Further, a reference voltage of the amplifier circuit may be commonly applied from the VREF terminal. An output signal from the buffer amplifier 26 is inputted to a sample/hold circuit 27. An output signal from the sample/hold circuit 27 is inputted to a buffer amplifier 28. An output signal from the buffer amplifier 28 is inputted to a transmission gate 29. An output signal from the transmission gate 29 is supplied to an output terminal VOUT2. Note that the transmission gate 29 may be omitted if not required.

FIG. 8 is a circuit diagram showing a sample/hold circuit according to the embodiment of the present invention, which applies to the sample/hold circuits 21 and 27. The sample/hold circuit includes a transmission gate 30, a dummy switch 31, and a capacitor C1. In the sample hold circuit, for the purpose of canceling pulse noises of øSH and øSHX (inverted øSH) with each other, PMOS and NMOS transistors in the transmission gate 30 are designed to have the same transistor size, and a gate area of the NMOS and PMOS transistors in the dummy switch 31 is set half the gate area of the transistors in the transmission gate.

FIG. 9 is a circuit diagram showing a buffer amplifier according to the embodiment of the present invention. The circuit includes an operation amplifier 32 and applies to the buffer amplifiers 22, 23, 26, and 28. Note that the buffer amplifier may be a source follower amplifier.

FIG. 10 is a circuit diagram showing an amplifier circuit according to the embodiment of the present invention. The amplifier circuit includes the operational amplifier 32 and a resistor. When used in place of the buffer amplifier 26, this circuit can increase an amplification rate of the signal processing circuit. Also, the reference voltage VREF of this amplifier circuit may be commonly supplied from the VREF terminal of FIG 11.

FIG. 11 is a circuit diagram showing a subtracter according to the embodiment of the present invention. The subtracter includes the operational amplifier 32 and a resistor. In this circuit, a voltage obtained by subtracting a voltage applied to a terminal INM from a voltage applied to a terminal INP is multiplied by a gain value determined according to a resistance ratio, and the resultant is outputted with the voltage of the VREF terminal as a reference. When the input terminals INP and INM are reversed, the output can be inverted with the voltage of the VREF terminal as a reference.

FIG. 12 is a circuit diagram showing a clamp circuit according to the embodiment of the present invention which applies to the clamp circuit 25. The clamp circuit includes the transmission gate 30, the dummy switch 31, and a capacitor 33. In the clamp circuit, with a view to canceling pulse noises of øCLAMP and øCLAMPX (inverted øCLAMP) with each other, PMOS and NMOS transistors in the transmission gate 30 are designed to have the same transistor size, and a gate area of the NMOS and PMOS transistors in the dummy switch 31 is set half the gate area of the transistors in the transmission gate.

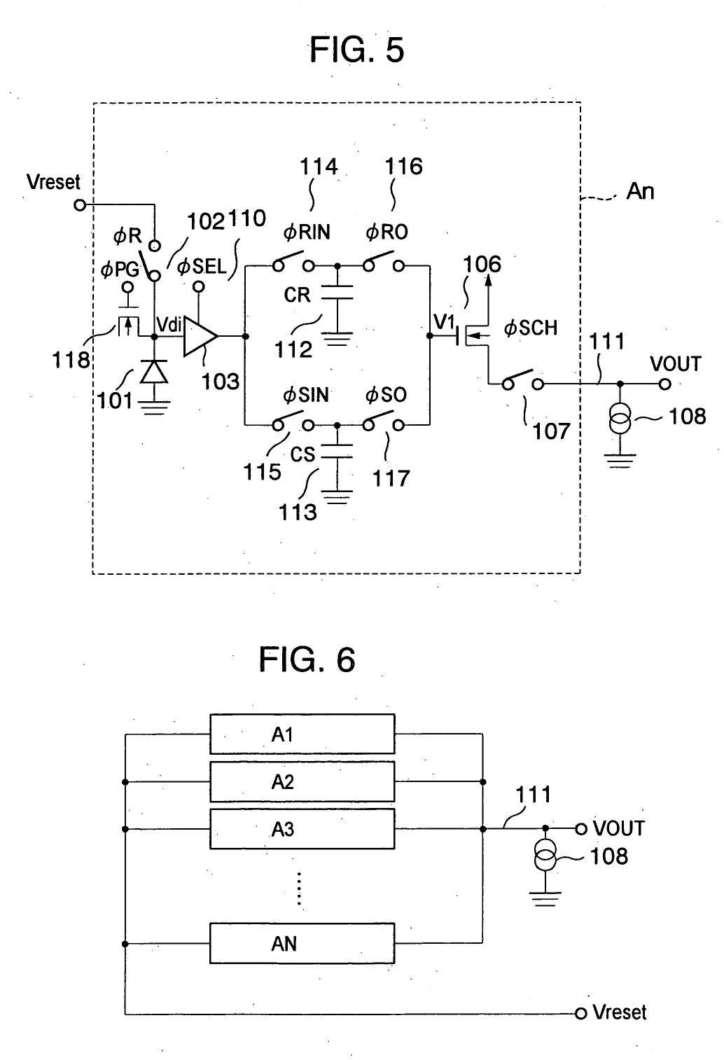

FIG. 5 is a schematic circuit diagram showing a photoelectric conversion block An in the photoelectric conversion device 43 according to the embodiment of the present invention. The photoelectric conversion device 43 according to the embodiment of the present invention includes the photoelectric conversion blocks An (block within a frame) of FIG. 5 in a number corresponding to the number of pixels. A channel selection switch 107 of each photoelectric conversion block An is connected to a common signal line 111. Note that the photoelectric conversion block. An corresponds to a photoelectric conversion block of an n-th bit. FIG. 6 is an overall structural diagram showing the photoelectric conversion device 43.

This circuit includes: a photodiode 101 as a light-receiving element: an NMOS gate 118; transfer switches 114, 115, 116, and 117 as charge transfer means; a reset switch 102 as reset means; an amplifying means 103; a capacitor 113 for holding optical signals; a capacitor 112 for holding reference signals as a reference for photoelectric conversion means; a MOS transistor 106: constituting a MOS source follower as signal reading means; the channel selection switch 107 as channel selection means; the common signal line 111; and a current source 108.

Note that the photodiode 101 is representative of the N-type semiconductor region 54 including the N-type diffusion layer 65 of FIG. 1, and the NMOS gate 118 is representative of a structure between the gate electrode 56 and the substrate region 60. In addition, the reset switch 102 is representative of the reset circuit 58 of FIG. 1, and the source follower circuit 57 constitutes a part of the amplifying means 103.

A control signal øPG is applied to a gate of the NMOS gate 118. One terminal of the reset switch 102 is connected to a Vreset terminal. As shown in FIG.6, all the photoelectric conversion blocks (A1 to An) share the Vreset terminal.

The amplifying means 103 may be constituted of a MOS source follower, a voltage follower amplifier, or the like and provided with an amplification enable terminal 110 for selecting a certain operation state.

Output signals from an output terminal VOUT of the photoelectric conversion device are inputted to the input terminal VIN of the signal processing circuit 42. The photoelectric conversion device and the signal processing circuit can be mounted on a single semiconductor substrate.

Hereinafter, description will be given of four operation methods for the signal processing circuit 42 and the photoelectric conversion device 43 according to the embodiment of the present invention.

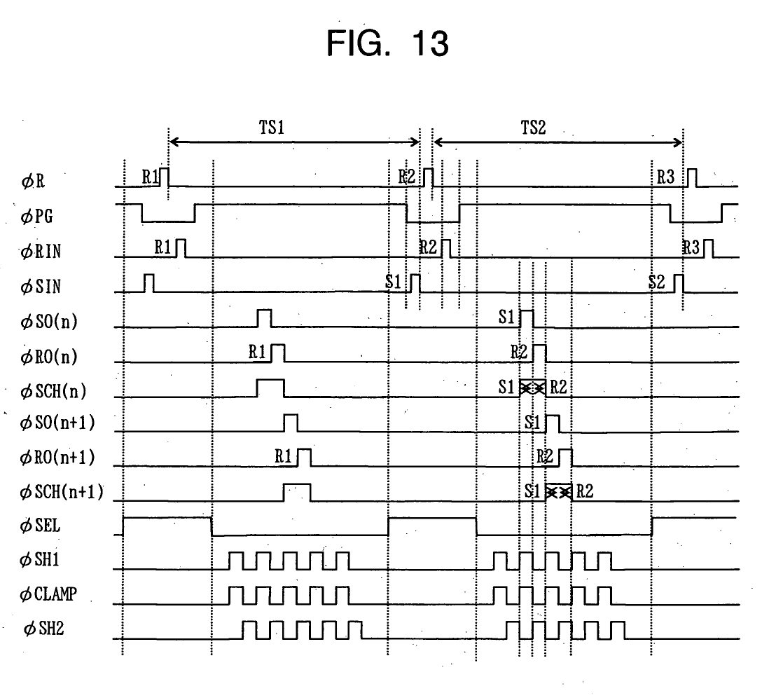

FIG. 13 is a timing chart illustrative of a first operation method for the signal processing circuit 42 and the photoelectric conversion device 43 according to the embodiment of the present invention. Referring to this timing chart, an operation of the photoelectric conversion device 43 will be described below. Regarding an operation of the image sensor IC 41 according to the present invention, an initialization operation of all the photoelectric conversion blocks (A1 to An) and a photocharge accumulation operation of the photogenerated carriers Qp are performed in synchronism with each other at a given timing. The photogenerated carriers Qp of the n-th bit during the photocharge accumulation operation at a first timing TS1 are set as Qp1n. At a second timing TS2, while all the photoelectric conversion blocks (A1 to An) accumulate new photogenerated carriers Qp2n, the photogenerated carriers Qp1n of first to last bits accumulated at the first timing TS1 are sequentially outputted from the image sensor IC 41 on a bit basis through the signal processing circuit 42 (background output) More specifically, operations of øR, øPG, øRIN, øSIN, and øSEL are synchronous with each other with respect to all the photoelectric conversion blocks (A1 to An) (hereinafter, this photoelectric conversion block may be referred to as “bit”). On the other hand, operation timings of øSO, øRO, and øSCH are different according to the bits and are marked with (n).

First, an operation of the photoelectric conversion block of the n-th bit will be described. When the reset switch 102 is turned ON while øPG is set to a low potential, a voltage applied to an output terminal Vdi of the photodiode 101 is fixed to the reference voltage Vreset. In contrast, when the reset switch 102 is turned OFF, the voltage applied to the output terminal Vdi reaches a voltage value equivalent to the voltage Vreset added with an off noise. The transfer switch 114 is turned ON in response to a pulse at R1 of øRIN as soon as the reset switch 102 is turned OFF. Reference signals after the initialization operation of the photodiode 101 are read out and accumulated in the capacitor 112.

In a subsequent photocharge accumulation operation at the first timing TS1, a potential of øPG is set high, and photocharges trapped by the channel of the NMOS gate 118 and the photodiode 101 are accumulated. The photocharges are accumulated in the channel of the NMOS gate 118 and the photodiode 101. A potential of Vdi varies depending on an amount of photocharges. The accumulation period extends from the completion of the pulse at R1 of øR to start of a pulse at S1 of øSIN (next pulse period) and thus corresponds to a period of the first timing TS1 of FIG. 13. The accumulation period is the same with respect to all the bits. During this period, when the photodiode receives a radiation noise from the outside, a potential of the photodiode varies. However, the structure of the present invention blocks the radiation noise, whereby the potential variation in the photodiode due to the radiation noise is kept small.

Upon completion of the accumulation, the potential of øPG is set low, the channel of the NMOS gate 118 is made to disappear, and the photocharges are moved to the N-type semiconductor region 54 constituting a cathode of the photodiode 101. The transfer switch 115 is turned ON in response to the pulse at S1 of øSIN, and the photogenerated carriers Qp obtained after the photocharges trapped by the photodiode 101 and the NMOS gate 118 are accumulated are read out and accumulated in the capacitor 113. At this point, a potential of øPG is set low. Subsequently, prior to a photocharge accumulation operation at the second timing TS2, the initialization operation is repeated, and then a potential of øPG is set high, followed by repeating the next accumulation operation.

Next, an operation for reading a reference signal and optical signal will be explained. During the accumulation period TS2 of FIG. 13, the channel selection switch 107 is turned ON in response to a pulse of øSCH(n) and at the same time, the transfer switch 117 is turned ON in response to a pulse of øSH(n), whereby optical signals held in the capacitor 113 are read out to the common signal line 111. This period corresponds to “S1” of øSCH(n). The optical signals are those stored during the period TS1; a reset voltage (reset in response to the pulse at R1 of øR) is used as a reference.

Next, when the transfer switch 116 is turned ON in response to a pulse of øRO(n) reference signals held in the capacitor 112 are read out to the common signal line 111. The reference signals are signals reset in response to the pulse at R2 of øR. By calculating a difference between the optical signal and the reference signal in the subsequent signal processing circuit 42, a voltage difference resulting from a light intensity difference can be obtained.

Subsequently, øSCH(n) is turned OFF, and then the channel selection switch 7 of a subsequent bit is turned ON in response to a pulse of øSCH(n+1) and the transfer switch 107 of a subsequent bit is opened in response to a pulse of øSO(n+1) to thereby start reading of optical signals of a subsequent bit. Other pulses of an (n+1)th bit are all generated with a delay corresponding to an ON-state period of øSCH from the pulse of the n-th bit.

As discussed above, an optical signal of the n-th bit, a reference signal of the n-th bit, an optical signal of the (n+1)th bit, and the reference signal of the (n+1) th bit are outputted from the terminal VOUT in the stated order. In the following description, an output period of optical signals and an output period of reference signals are referred to as a “previous period” and a “latter period” for ease of explanation.

An operation of the signal processing circuit 42 will be explained next. An output signal from the terminal VOUT is inputted to the terminal VIN. A sample/hold pulse øSH1 is turned ON after output of optical signals starts and turned OFF before the output of the optical signals ceases. The optical signals are thereby subjected to sample/hold processing. Signals from the terminal VIN and the signals having undergone sample/hold processing are inputted to the subtracter. In the previous period, similar optical signals are inputted to the subtracter, while in the latter period, the reference signal and the optical signal having undergone sample/hold processing are inputted to the subtracter. Therefore, an output voltage of the subtracter corresponds to a VREF level in the previous period and to the VREF level (voltage) added with a level (voltage) calculated by multiplying a difference between the optical signal and the reference signal by a gain value, in the latter period. In addition, an output voltage in the previous period is inclusive of an offset voltage in the buffer amplifiers 22, 23 and an offset voltage of the subtracter 24. Meanwhile, an output voltage in the latter period is inclusive of an offset voltage in the buffer amplifiers 22, 23, an offset voltage in the subtracter 24, and an offset voltage in the sample/hold circuit 21.

The clamp pulse øCLAMP is applied so as to turn ON before øSH1 is turned ON and turn OFF before øSH1 is turned OFF. Thus, an output voltage of the clamp circuit 25 is clamped to the VREF level in the previous period and, in the latter period, to the VREF level (voltage) added with a level (voltage) obtained by subtracting the output voltage of the subtracter in the previous period from that in the latter period. As a result, the output voltage of the clamp circuit in the latter period involves neither the offset voltage of the buffer amplifiers 22, 23 nor the offset voltage of the subtracter 24. Also, the sample/hold circuit 21 involves the small offset voltage because of its circuit configuration where noises of the pulses øSH and øSHX (inverted øSH) are cancelled. Based on the above, the output voltage of the clamp circuit in the latter period reaches the VREF level (reference) added with a level obtained by multiplying a difference between the optical signal and the reference signal by a gain value.

The sample/hold pulse øSH2 is turned ON before and after output of reference signals starts and turned OFF before the output of the reference signals ceases. With this operation, the output signals in the latter period, after the clamp operation are sampled to hold the output signals in the previous period of a subsequent bit. Thus, the output level can be kept for a long time.

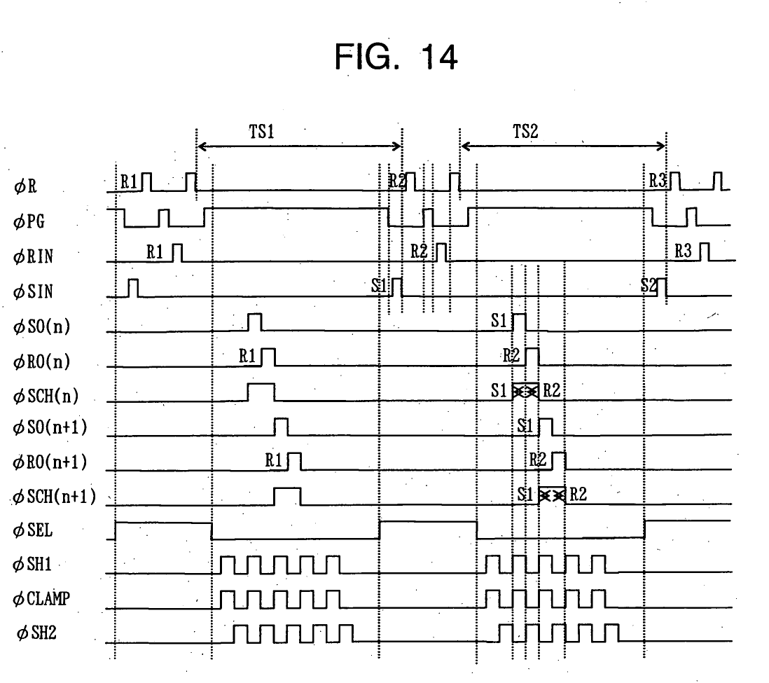

FIG. 14 is a timing chart illustrative of a second operation method for the photoelectric conversion apparatus 43 and the signal processing circuit 42 according to the embodiment of the present invention. Referring to the timing chart, description is focused on a point different from the first operation method.

The second operation method involves the following operation in addition to the first operation method. That is, øRIN is turned ON after øPG is turned ON/OFF, and øRIN is turned OFF, followed by turning ON/OFF øR.

Thus, the same noise state is attained when the signal voltage is read out in response to the pulse øSIN and when the reference voltage is read out in response to the pulse øRIN.

In other words, the first operation method has a possibility of causing a difference between the reference voltage and the signal voltage according to an operation of turning ON/OFF the pulse øPG, in a dark state However, the second operation method eliminates the possibility of causing a difference between the reference voltage and the signal voltage in a dark state since the operation of turning ON/OFF the pulse øPG is effected only once after the reset operation, for both the reference voltage and the signal voltage.

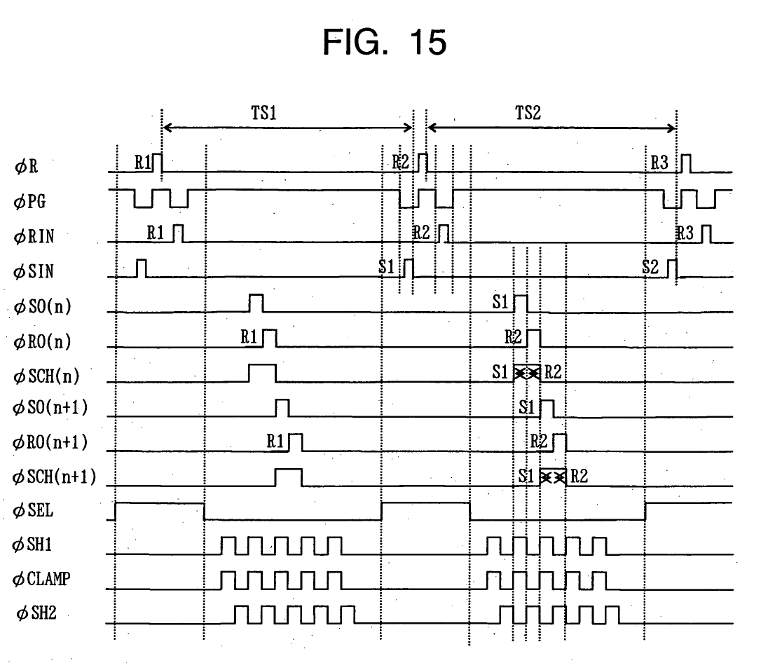

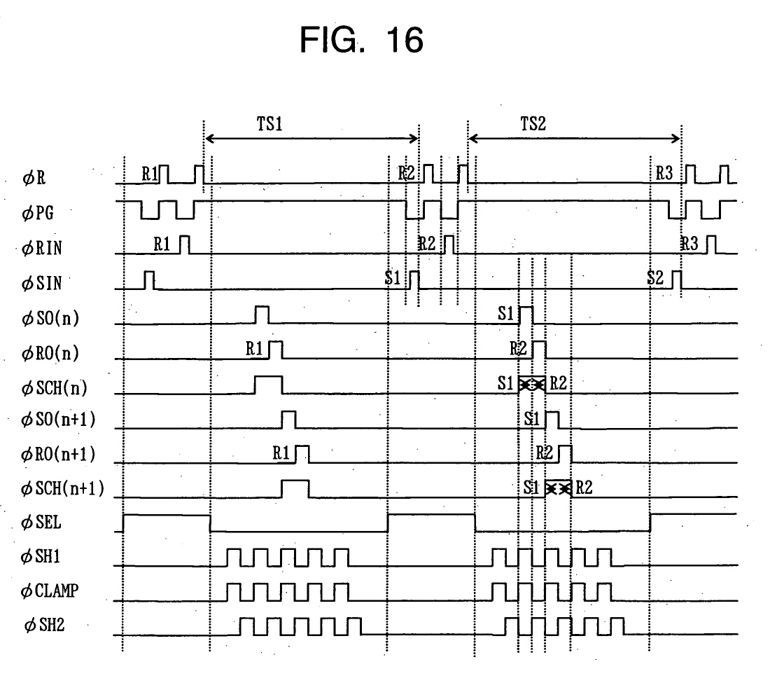

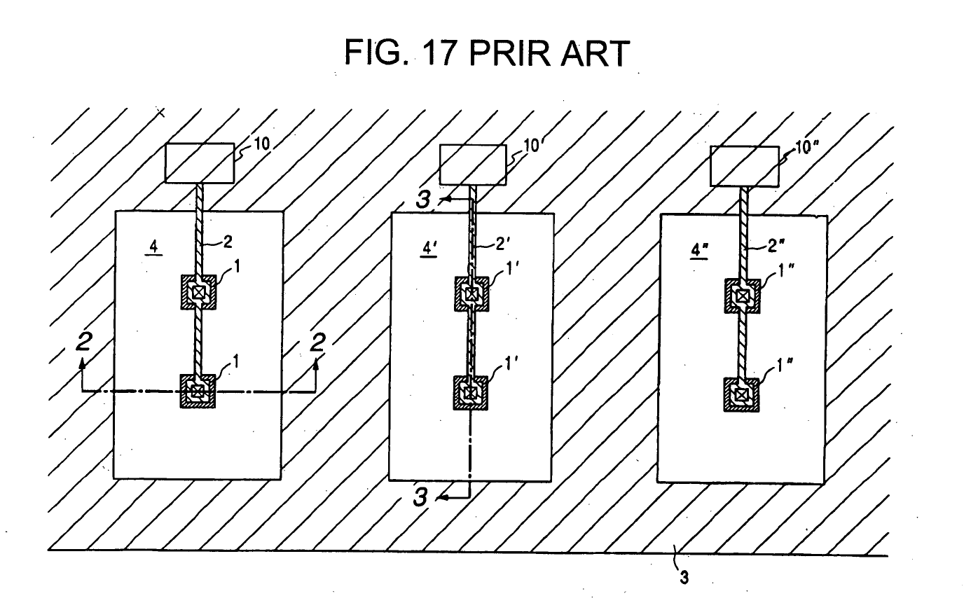

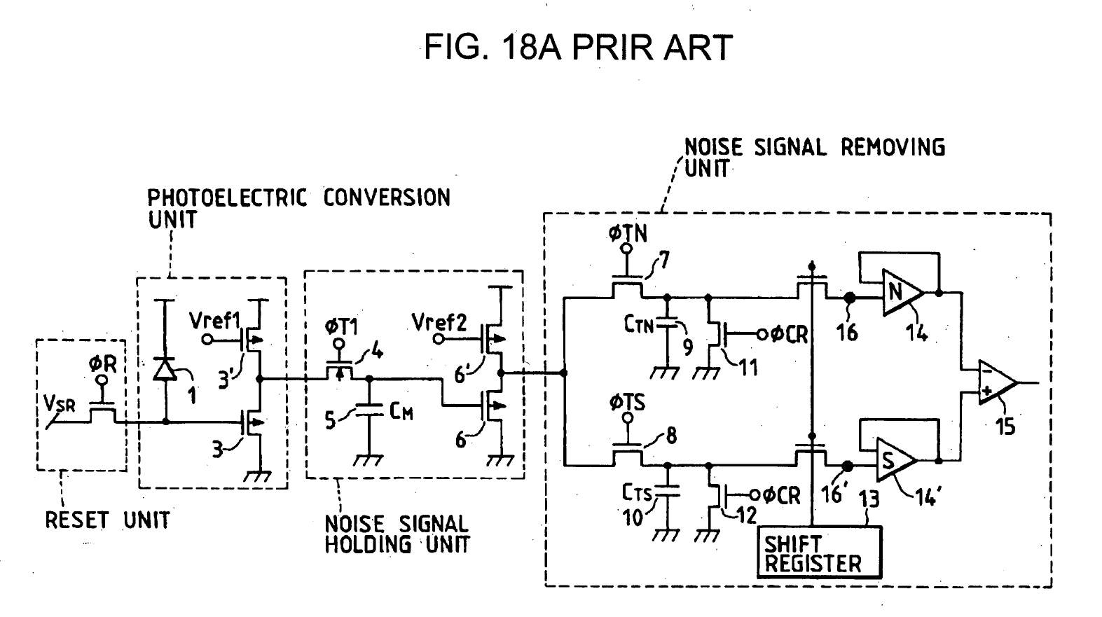

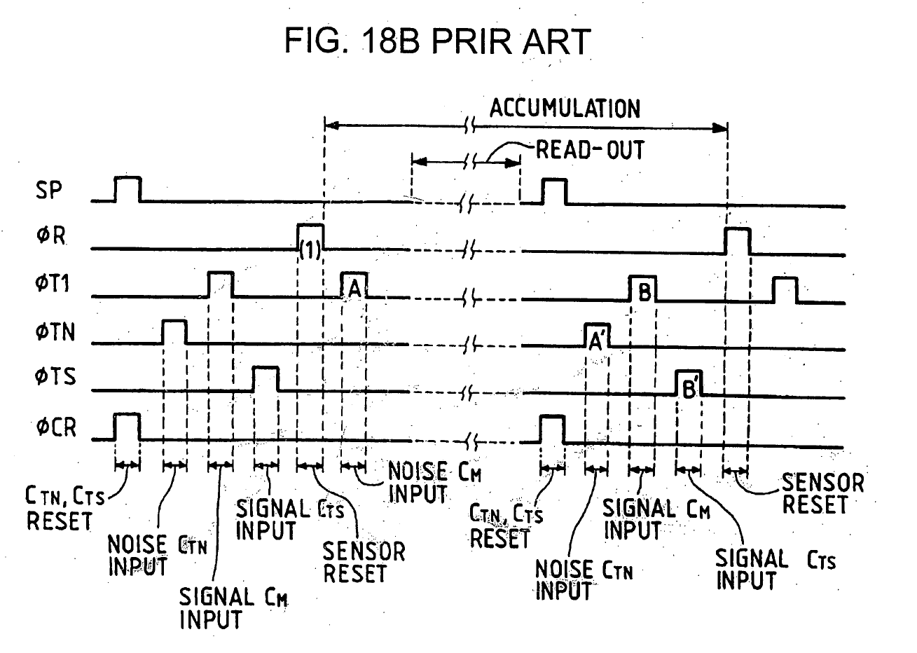

FIG. 15 is a timing chart illustrative of a third operation method for the photoelectric conversion apparatus 43 and the signal processing circuit 42 according to the embodiment of the present invention. Referring to the timing chart, description is focused on a point different from the first operation method.

The third method involves the following operations in addition to the operations of the first operation method. That is, at the time of turning OFF øR, øPG is turned ON. This makes it possible to form the channel 71 at the time of the reset operation and increase the capacitance Cpd of the photodiode portion, with the result that the reset noise (noise at the reset time) can be minimized on the basis of the equation (2).

FIG. 16 is a timing chart illustrative of a fourth operation method for the photoelectric conversion apparatus 43 and the signal processing circuit 42 according to the embodiment of the present invention. Referring to the timing chart, description is focused on a point different from the third operation method.

The fourth operation method involves the following operations in addition to the third operation method. That is, øRIN is turned OFF, and øPG is turned ON, and then øR is turned ON/OFF. Thus, the same noise state is attained when the signal voltage is read out in response to the pulse øSIN and when the reference voltage is read out in response to the pulse øRIN.

In other words, the third operation method has a possibility of causing a difference between the reference voltage and the signal voltage according to an operation of turning ON/OFF the pulse øPG, in a dark state. However, the fourths operation method eliminates the possibility of causing a difference between the reference voltage and the signal voltage in a dark state since the operation of turning OFF the pulse øPG is effected only once after the reset operation, for both the reference voltage and the signal voltage.

According to the above embodiments, the optical signals accumulated in the pervious period, i.e., the accumulation period TS1 can be read during the accumulation operation of the photodiode in the period TS2. Accordingly, LEDs in three colors, RGB are switched ON in order to thereby read color image data. For example, an LED in red (R) is switched ON during the period TS1 to thereby read image data of red components. An LED in green (G) is switched ON during the period TS2 to thereby read image data of green components. An LED in blue (B) is switched ON during a period succeeding the period TS2 to thereby read image data of blue components.

In this case, an optical signal in red is read out during the period TS2. In the above description about the image sensor according to the present invention, it is not always necessary to incorporate the signal processing circuit 42 into an IC.

The foregoing explanation is centered on the linear image sensor IC, but the structure of FIGS. 1 and 3 is applicable to an area image sensor IC.

The present invention has been described so far but the invention should not be construed as being limited to the aforementioned respective embodiments. The present invention can be implemented in various modifications without departing from the gist of the present invention.

The present invention is applicable to the linear image sensor IC adapted for an image reading apparatus such as a facsimile machine or image scanner and a close contact type image sensor having the plural image sensor ICs mounted thereon. The present invention is applicable to the area image sensor IC as well.

1. A photoelectric conversion device, comprising a light-receiving element that includes:
a first semiconductor region of a first conductivity type for forming a light-receiving portion;
a second semiconductor region of a second conductivity type formed on a surface of the first semiconductor region; and
a gate electrode formed near the second semiconductor region above the surface of the first semiconductor region through an insulator,
wherein the light-receiving element allows control of a state of the surface of the first semiconductor region below the gate electrode between two states consisting of an inversion state and an accumulation state by switching a voltage applied to the gate electrode.

2. A photoelectric conversion device according to claim 1, wherein the light-receiving element further includes a third semiconductor region of the second conductivity type having an impurity concentration lower than an impurity concentration in the second semiconductor region and formed between the first semiconductor region and the second semiconductor region.

3. A photoelectric conversion device according to claim 1, wherein a channel formed in the inversion state in the first semiconductor region below the gate electrode is electrically connected to the second semiconductor region.

4. A photoelectric conversion device according to claim 1, further comprising:
reset means for initializing the second semiconductor region; and
amplifying means for generating an amplification signal based on a signal of the second semiconductor region.

5. A photoelectric conversion device according to claim 1, wherein the gate electrode is formed of polysilicon.

6. A photoelectric conversion device according to claim 1, wherein the gate electrode is formed of a transparency conductive film.

7. A photoelectric conversion device according to claim 1, wherein:
the surface of the first semiconductor region below the gate electrode is brought into the inversion state when the light-receiving element accumulates photo charges; and
the surface of the first semiconductor region below the gate electrode is brought into the accumulation state when the light-receiving element reads an optical signal.

8. A photoelectric conversion device, comprising a light-receiving element that includes:
a first semiconductor region of a first conductivity type for forming a light-receiving portion;
a second semiconductor region of a second conductivity type formed on a surface of the first semiconductor region;
a gate electrode formed near the second semiconductor region above the surface of the first semiconductor region through an insulator; and
a third semiconductor region of the second conductivity type having an impurity concentration lower then an impurity concentration in the second semiconductor region and formed between the first semiconductor region and the second semiconductor region,
wherein the light-receiving element allows control of a state of the surface of the first semiconductor region below the gate electrode between two states consisting of an inversion state and an accumulation state by switching a voltage applied to the gate electrode.

9. A photoelectric conversion device according to claim 8, wherein a channel formed in the inversion state in the first semiconductor region below the gate electrode is electrically connected to the second semiconductor region.

10. A photoelectric conversion device according to claim 8, further comprising:
reset means for initializing the second semiconductor region; and
amplifying means for generating an amplification signal based on a signal of the second semiconductor region.

11. A photoelectric conversion device according to claim 8, wherein the gate electrode is formed of polysilicon.

12. A photoelectric conversion device according to claim 8, wherein the gate electrode is formed of a transparency conductive film.

13. A photoelectric conversion device according to claim 8, wherein:
the surface of the first semiconductor region below the gate electrode is brought into the inversion state when the light-receiving element accumulates photo charges; and
the surface of the first semiconductor region below the gate electrode is brought into the accumulation state when the light-receiving element reads an optical signal.

14. An image sensor IC which has the photoelectric conversion device according to claim 1.

15. An image sensor IC which has the photoelectric conversion device according to claim 8.
